(19) United States
(12) Patent Application Publication
(10) Pub. No.: US 2005/0174169 A1
(43) Pub. Date: Aug. 11, 2005

(54) Method of measuring microwave power and device for carrying out said method

(75) Inventors: Jean-Francois Jarno, Antony (FR); Francois Rousseaux, Marcoussis (FR)

Correspondence Address: LOWE HAUPTMAN GILMAN & BERNER, LLP, 1700 DIAGNOSTIC ROAD, SUITE 300, ALEXANDRIA, VA, 22314, US

(73) Assignee: THALES, Neuilly/Sur/Seine (FR)

(21) Appl. No.: 10/509,381

(22) PCT Filed: Mar. 18, 2003
(86) PCT No.: PCT/FR03/00861

(30) Foreign Application Priority Data
Mar. 29, 2002 (FR) 02/03974

(51) Int. Cl. H03F 3/58

(52) U.S. Cl. 330/43

(57) ABSTRACT

The invention relates to a method of measuring the RF output power (Ps) of a microwave tube amplifier, the tube having an electron gun delivering an electron beam, an RF circuit for interaction between an RF signal and the electron beam, the RF circuit having an amplified RF signal output, and a collector having at least two electrodes for collecting the electron bream. The RF output power as amplified RF signal output is determined from the measurement of the current Ic1 coming from the first electrode closest to the gun, a calculation of the RF output power (Ps) being carried out through a predetermined relationship between said current and the output power of the amplifier. The invention also relates to a device that includes measurement means for implementing the measurement method.

This invention relates to an amplifier equipped with microwave traveling wave tubes (TWTs) which constitute the final stage of telecommunication transmitters used in ground-satellite and satellite-ground links. They may also be used in other types of transmitters intended, for example, for military, scientific, metrology, telecommunication, terrestrial-link and radio beam applications, etc.

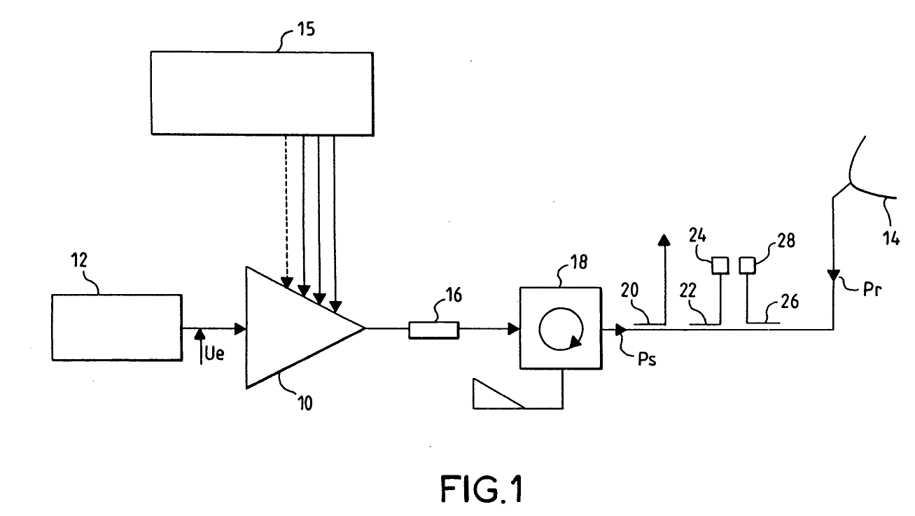

FIG. 1 is a diagram showing the principle of this final stage, which comprises a microwave tube 10 of the TWT type fed with a signal Ue which is a modulated electromagnetic wave coming from a low-level multistage preamplifier 12. This signal is of the order of a few tens of milliwatts at a frequency lying within a “telecommunication” band, for example the 12.75-14.50 GHz band. The amplifier feeds a load, which in this example is a transmission antenna 14. A supply 15 delivers the various high voltages needed to operate the tube.

The TWT 10 is a depressed-collector TWT. Its output is on a rectangular or coaxial waveguide, for example WR 75. A filter 16 at the output side of the TWT is imposed by the “telecommunications” standards; it prevents the transmission of undesirable frequencies that would be generated because of the nonlinearities of the TWT. A circulator 18 after the filter 16 prevents any inopportune reflection of microwave energy toward the tube.

A first coupler 20 on the output side of the circulator 18, which is followed by suitable transitions and cables, makes it possible to have available on a front face of the amplifier a specimen of the output power Ps of the amplifier for measurement, if required, by the user.

A second coupler 22 on the output side of the circulator, followed by a high-frequency (HF) detector 24 and suitable cables and transitions, makes it possible to generate a signal representative of the output power Ps, needed for correct operation of the device (not shown in the figure) for controlling and regulating the TWT.

A third coupler 26, followed by another HF detector 28, likewise makes it possible to generate a signal representative of the power Pr reflected by the user, in this case by the transmission antennae 14. This reflected power signal is often used in a threshold system, thereby making it possible to safeguard all the equipment in the event of substantial mismatching of this use. Associated with the second 22 and third 26 couplers are, of course, tables and, for example, calibration charts.

These TWT output measurement devices are expensive, firstly because of the number of couplers, RF detectors and HF transitions used and secondly because of the adjustments and calibrations needed depending on the transmission power and frequencies.

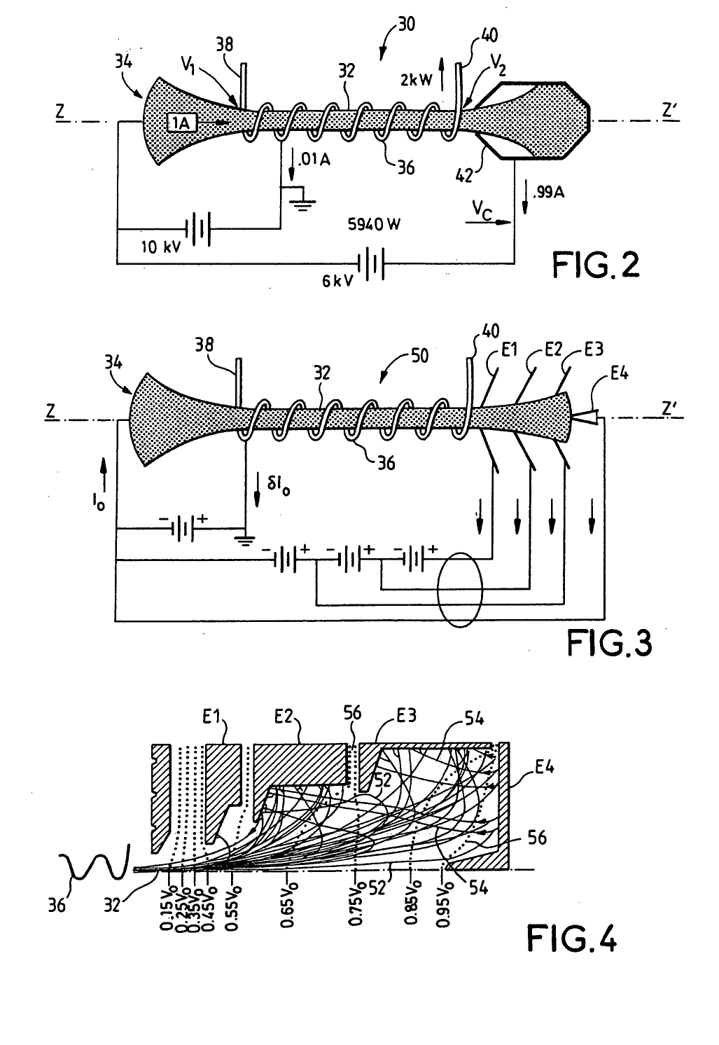

FIG. 2 shows a simplified diagram of a traveling wave tube 30. A relatively filiform cylindrical electron beam 32, emitted by a cathode 34 of the TWT, travels along the ZZ′ axis of a metal helix 36. An RF input signal to be amplified is injected, at a first end 38 of the helix, at the frequency F. The interaction between the electron beam 32 and the electromagnetic signal propagating along the helix 36 is such that the electrons bunch into periodic packets, at the frequency F, and yield up their energy to the radiofrequency (RF) input signal which is thus amplified and extracted at the other end 40 (RF output) of the helix. Very schematically, the electrons thus yield up 20 to 30% of their energy to the RF input signal. This percentage of energy yield (20 to 30%) is called the “electrical yield”. After having left the helix, the electrons penetrate a collector 42 in which they have to dissipate, in thermal form, the remaining 80 to 70% of their kinetic energy.

In fact, the collector 42 is raised to a potential Vc that allows the electrons to be slowed down before they strike the walls of the collector. The maximum value of the collector voltage Vs is dictated by the preclusion of the electrons being reflected back toward the helix. FIG. 2 illustrates this phenomenon.

In the example proposed, the electrons enter the helix at a velocity V₁ corresponding to a voltage of 10 kV. After having yielded up 2 kW, they leave the helix at a lower velocity V₂, which corresponds to 8 kV since the beam is a 1 A beam. The voltage Vc of the collector was chosen to be 6 kV relative to the cathode. No electron is therefore reflected. The collector voltage Vc could even have been chosen to be much lower, for example 2 kV, beyond which value the electrons would have been reflected. In fact, the electrons do not leave at the velocity V₂ but with a dispersion of velocities, which is often quite large, about V₂, hence the margin adopted in the choice of Vc.

The deceleration of the electrons by the collector voltage Vc reduces the energy to be thermally dissipated on the walls, and therefore the energy taken from the high-voltage supply for the electron beam. The overall yield therefore becomes higher.

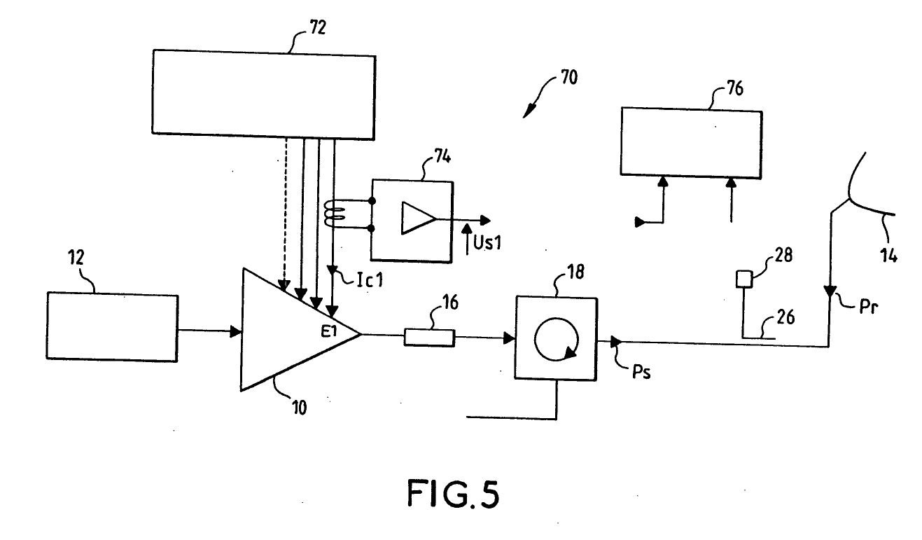

In addition, this increase in the yield is greater if a multi-electrode or <<multistage>> collector is used instead of a single depressed collector. FIG. 3 shows such a traveling wave tube comprising a four-stage collector E1, E2, E3, E4. The function of the first stage E1 is to decelerate and collect the slowest electrons, that of the final stage E4, at the back of the collector, to decelerate and collect the fastest electrons.

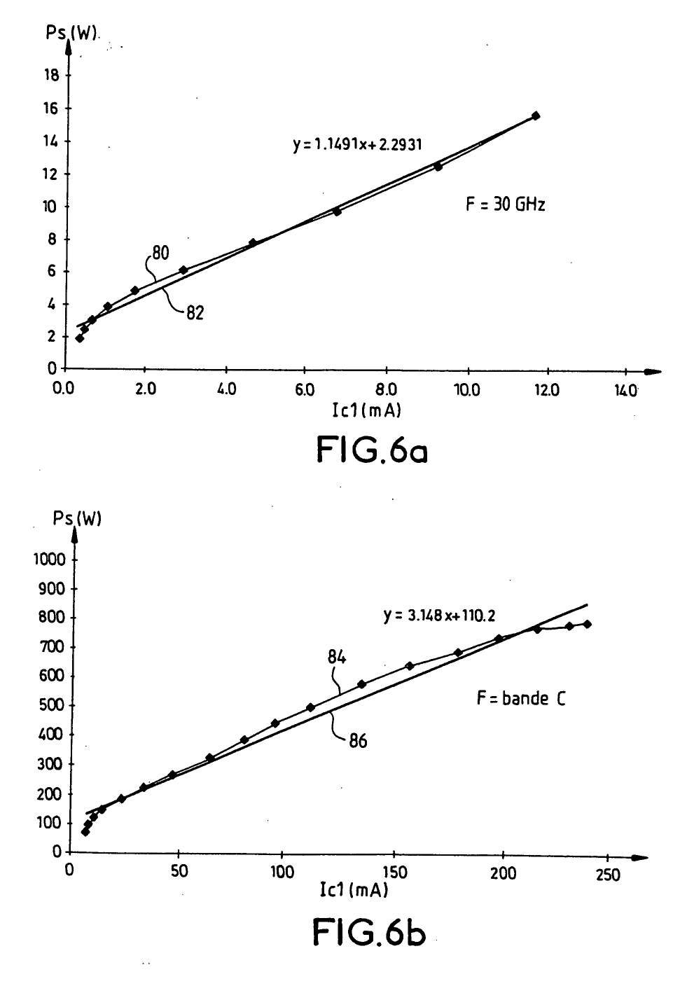

FIG. 4 shows a cross section in the region of the electrodes E1, E2, E3 and E4 of the collector of such a four-stage TWT tube. The electron beam 32, leaving the helix 36 and arriving in the collector region, is dispersed along direct paths 52 (in solid lines) and secondary paths 54 toward the four electrodes. The dotted lines show the equipotentials 56.

Recent measurements carried out within the context of improving the operation of a TWT in telecommunication transmitters have shown that there exists, for example in the case of a TWT with a two-stage depressed collector, a relationship between the high-frequency output power Ps of the TWT and the collector current. This is because the current Ic1 generated by the first stage E1 of the collector is an increasing, single-valued function of the degree of modulation of the beam current and therefore of the high-frequency output power Ps.

A first object of the invention is to simplify the measurements of the output power of a microwave tube amplifier.

Another object is to reduce the cost of the amplifier by eliminating parts and adjustments needed in the prior art for measuring the power of microwave tube amplifiers.

For this purpose, the invention provides a method of measuring the RF output power of a microwave tube amplifier, the tube having an electron gun delivering an electron beam, an RF circuit for interaction between an RF signal and the electron beam, the RF circuit having an amplified RF signal output, a collector having at least two electrodes for collecting the electron beam, these electrodes being respectively separated from the gun by increasing distances, the first electrode being closest to the gun, characterized in that the RF output power as amplified RF signal output is determined from the measurement of the current Ic1 coming from the first electrode, a calculation of the RF output power being carried out through a predetermined relationship between said current Ic1 and the output power of the amplifier.

The proposed simplification therefore consists in replacing the direct measurement and/or the HF detection of the RF output power Ps with the single measurement of the current Ic1 of the first collector electrode of the tube.

This measurement of Ic1 is sufficiently accurate to satisfy the indication of the front face power of the amplifier and above all to meet the needs of controlling the overall supply for the TWT, the processing logic for the amplifier and the various signal processing operations.

The measurement of the current Ic1 may be carried out directly at low voltage, as will be seen later. This measurement therefore makes it possible, with potentially better accuracy than that of the prior art, to eliminate all the HF elements associated with the output power measurements, i.e. two couplers for measuring the output power Ps, an RF measurement diode, the connectors and the coaxial cables for connection to the frames.

The invention also relates to a microwave tube amplifier, the tube having an electron gun delivering an electron beam, an RF circuit for interaction between an RF signal and the electron beam, the RF circuit having an amplified RF signal output, a collector having at least two electrodes for collecting the electron beam, these electrodes being respectively separated from the gun by increasing distances, the first electrode being closest to the gun, characterized in that it includes first means for measuring the current Ic1 coming from the first electrode and second means for determining the RF output power from the measurement of this current Ic1.

The invention will be more clearly understood with the aid of illustrative examples according to the invention, with reference to the appended drawings in which:

FIG. 1; already described, is a diagram showing the principle of an amplifier comprising a microwave traveling wave tube;

FIG. 2, already described, shows a simplified diagram of a traveling wave tube (TWT);

FIG. 3, already described, shows a TWT having a multi-electrode or <<multistage>> collector;

FIG. 4, already described, shows a cross section in the electrode region of a four-stage TWT;

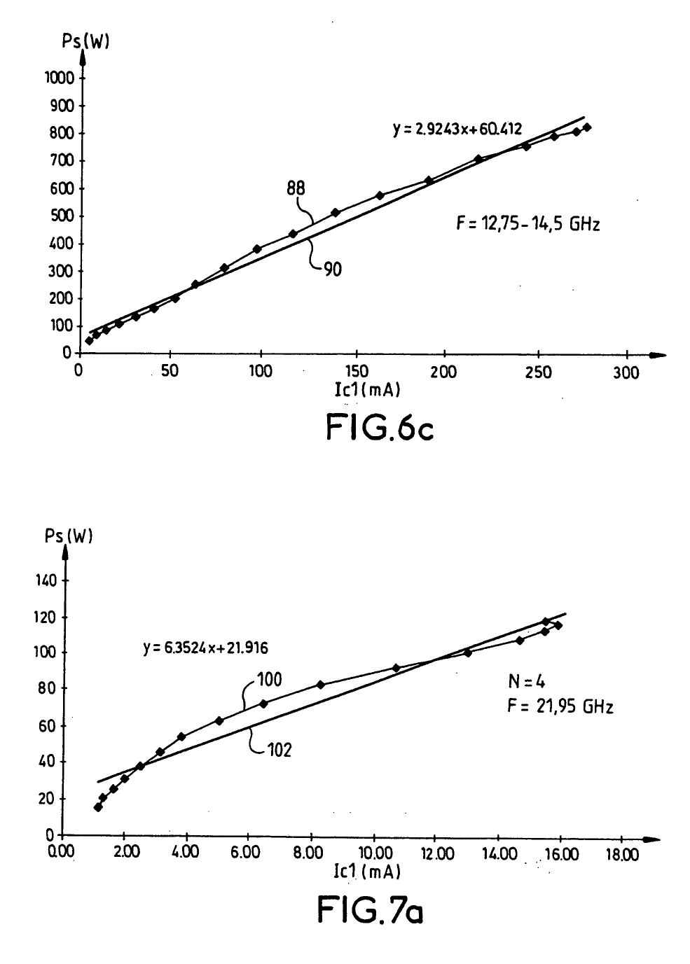

FIG. 5 is a diagram showing the principle of an amplifier according to the invention, that includes a TWT;

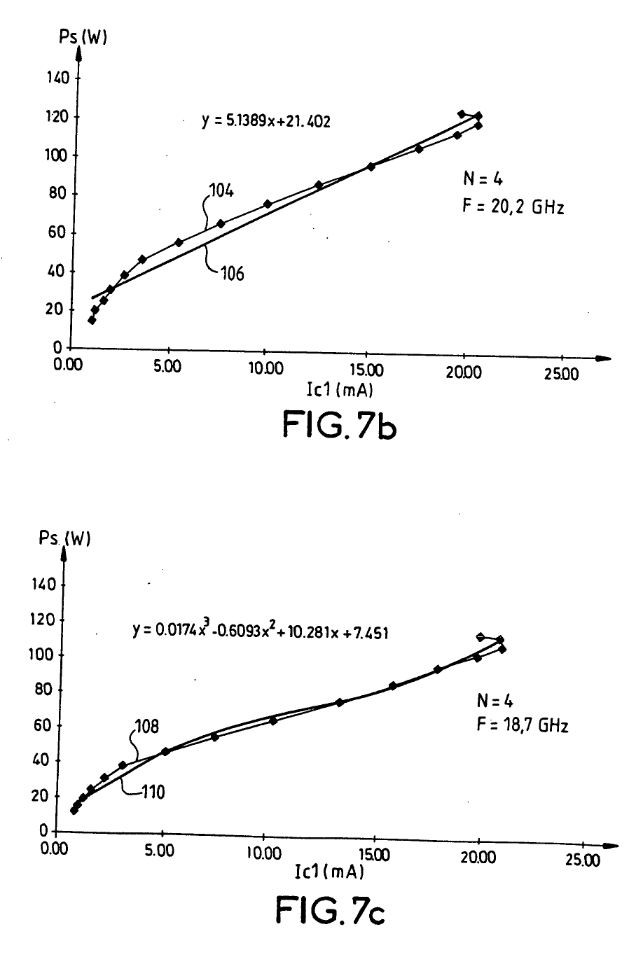

FIGS. 6a, 6b and 6c are curves showing the variation in the output power Ps as a function of the current of the first electrode of a two-stage TWT;

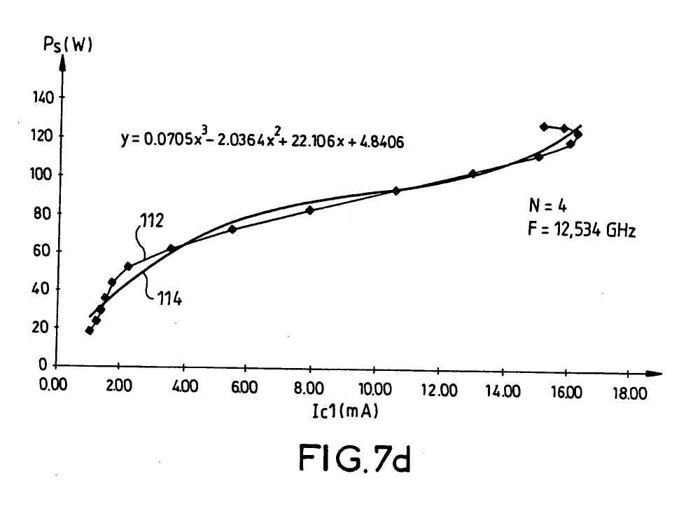

FIGS. 7a, 7b, 7c and 7d are curves showing the variation in the output power Ps as a function of the current of the first electrode of a four-stage TWT; and

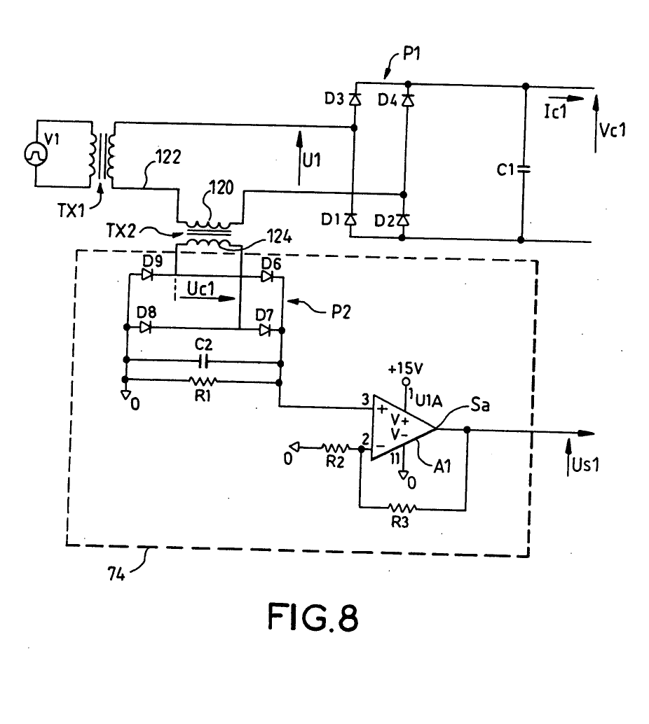

FIG. 8 shows a circuit for measuring the collector current of the amplifier of FIG. 5 according to the invention.

FIG. 5 is a diagram showing the principle of an amplifier 70 according to the invention, which includes a TWT. The amplifier 70 includes the microwave tube 10 of TWT type with a depressed collector fed with an RF input signal coming from the preamplifier 12. The amplifier feeds, via the filter 16 and the circulator 18, the transmission antenna 14. A supply 72 delivers the various high voltages needed to operate the tube.

The amplifier furthermore includes a circuit 74 for measuring the current Ic1 coming from the first electrode E1 of the TWT.

The relationship between the output power Ps and the current Ic1, in the case of a TWT having a two-stage (N=2) collector, can be likened approximately to a straight line given by Ps=k×Ic1, k being a constant. For such a type of TWT, this relationship varies or may vary with the operating frequency in the allocated band and will include a transmission frequency interpolation formula. The relationship Ps=f(Ic1) for several frequencies will therefore be input into a processing circuit 76 of the amplifier, as will an interpolation formula for all the frequencies other than the previous ones.

In the case of a two-stage collector, often encountered in TWTs for ground transmitters, the relationships, depending on the transmission frequency bands, which determine the output power Ps as a function of the current Ic1 of the first electrode E1, namely Ps=f(Ic1), are very close to straight lines. FIGS. 6a, 6b and 6c show, respectively, such relationships Ps=f(Ic1) for a transmission frequency F of 30 GHz, for a frequency in the C-band and for one in a 12.75-14.5 GHz frequency band, respectively.

FIG. 6a shows a curve 80, for the output power Ps as a function of the collector current Ic1 of the first stage of a TWT, with a nominal output power of 12 W, operating at 30 GHz. This curve 80 approximates to a straight line 82 of equation
Ps=1.1491×Ic1+2.2931 (1)

Ps being expressed in W and Ic1 in mA.

FIG. 6b shows a curve 64 of the output power Ps as a function of the current Ic1 of a TWT of 750 W nominal power operating in the C-band. This curve 84 can be approximated to a straight line 86 of equation:
Ps=3.148×Ic1+110.2 (2)

FIG. 6c shows another curve 88 for the output power Ps as a function of the current Ic1 of the 750-watt TWT of FIG. 5b operating in the 12.75-14.5 GHz frequency band. This other curve 88 can be approximated by a straight line 90 of equation:
Ps=2.9243×Ic1+60.412 (3).

Over the 10 dB power output Ps dynamic range of the TWT, the difference in measurement between the output power measured directly by conventional means and the output power Ps of the TWT measured indirectly from the current Ic1 of the first electrode, this difference remains less than 10% and depends, for low levels, on the sensitivity of the measurement of the collector current Ic1 of the electrode E1.

In the case of TWTs having more than two stages, for example four stages (N=4) such as those used on satellite TWTs, measurements, for various TWT transmission frequencies, of the output power Ps of the TWT as a function of the collector current Ic1 have been carried out in the same manner. These measurements are shown by the curves in FIGS. 7a, 7b, 7c and 7d. These curves can be likened to a monotonically increasing polynomial; they can also be likened to straight lines, although with more approximations than in the case of a two-stage TWT.

In the case of FIG. 7a of the four-stage TWT operating at 21.95 GHz, the output power Ps as a function of the collector current Ic1 of the first stage (curve 100), can be approximated to a straight line 102 of equation:
Ps=6.3524×Ic1+21.916 (4).

In the case of FIG. 7b, the four-stage TWT operates at 20.2 GHz and the output power Ps as a function of the collector current Ic1 of the first stage (curve 104), can be approximated to a straight line 106 of equation:
Ps=5.1389×Ic1+21.402 (5).

In the case of FIG. 7c, the four-stage TWT operates at 18.7 GHz and the output power Ps as a function of the collector current Ic1 of the first stage (curve 108), can be approximated to the function (curve 110) of equation:
Ps=0.0174×Ic1³−0.6093×Ic1²+10.281×Ic1+7.4151.

In the case of FIG. 7d, the four-stage TWT operates at 12.534 GHz, and the output power Ps as a function of the collector current Ic1 of the first stage (curve 112) can be approximated by the function (curve 114) of equation:
Ps=0.0705×Ic1³−2.0364×Ic1²+22.106×Ic1+4.8406.

Therefore, depending on the desired accuracy, a relationship Ps=f(Ic1) of greater or lesser complexity will be input into the processing circuit 76 of the amplifier, this being done at several frequency points in the allotted band. Again, as previously, an interpolation will allow operation at other frequencies.

FIG. 8 shows a circuit for measuring the collector current Ic1 of the first stage E1 of the TWT 10 of the amplifier of FIG. 5 according to the invention. The high-voltage supply 72 delivers, via a transformer TX1, an AC voltage U1 to a high-voltage rectifier bridge P1 comprising rectifying diodes D1, D2, D3, D4, that delivers the DC voltage Vc1 and the current Ic1 of the first electrode E1 of the TWT.

A current transformer TX2 of the measurement circuit 74 comprises a primary 120, in series with a wire 122 for supplying the high-voltage rectifier bridge P1 with AC current, and a secondary 124 that generates an AC voltage Uc1 proportional to the AC current in the wire 122 representative of the supply current Ic1 of the electrode E1. The voltage Uc1, after rectification by a diode D6, D7, D8, D9 bridge P2, is amplified by a conventional operational amplifier A1 which delivers, at its output Sa, a voltage Us1 proportional to the current Ic1 of the first electrode E1.

The processing circuit 76 of known type establishes the relationship, as described above, between the output voltage Us1 of the detector 74 representative of the current Ic1 and the output power Ps of the amplifier 70. This processing circuit 76 may be a computer using, for example, a microprocessor or any other calculating device.

The relationship Ps=f(Ic1), which, as mentioned above in the case of a two-stage collector, can be approximately likened to a straight line, varies or may vary according to the operation frequency in the allotted band. The relationship Ps=f(Ic1) for various frequencies will therefore be input into the calculating circuit 76 of the amplifier together with an interpolation formula for all frequencies other than the previous ones.

In this embodiment according to the invention shown in FIG. 5, the couplers followed by the suitable transitions and cables needed for the output power measurements have been eliminated, making the amplifier simpler and less expensive to construct.

The third coupler 26, for measuring the reflected power Pr, i.e. reflected by the user, may also be eliminated provided that the circulator 18 ensures that the TWT is protected.

In the case of TWTs in which the depressed collector has more than two stages, for example four stages such as those used in satellite TWTs, the curves giving the output power Ps of the TWT as a function of the current Ic1 of the first electrode, which are shown in FIGS. 7a, 7b, 7c and 7d, can be likened to a monotonically increasing polynomial; they can also be likened to straight lines, although with more approximations than in the case of two-stage TWTs.

To summarize, the amplifier according to the invention has the following advantages:
Measurement and/or detection of a TWT microwave output power is replaced by a simple current measurement. This DC measurement uses an AC-DC conversion, thereby further emphasizing the fact that the measurement is inexpensive;
Elimination of:
   one or two couplers
   one or two transitions
   detection diode(s)
   connectors and coaxial cables
   tricky power calibrations;
Substantial saving in terms of weight and volume compared with the necessary accessories in the prior art.

1. A method of measuring the RF output power (Ps) of a microwave tube amplifier, the tube having an electron gun delivering an electron beam, an RF circuit for interaction between an RF signal and the electron beam, the RF circuit having an amplified RF signal output, a collector having at least two electrodes for collecting the electron beam, these electrodes being respectively separated from the gun by increasing distances, the first electrode being closest to the gun, comprising the steps of:
determining the RF output power as amplified RF signal output from the measurement of the current coming from the first electrode; and
calculating the RF output power through a predetermined relationship between the current and the output power of the amplifier.

2. The method of measuring the RF power as claimed in claim 1, wherein the microwave tube is a TWT.

3. The method of measuring the RF power as claimed in claim 2, wherein the collector of the TWT comprises two electrodes and in that the relationship between the RF output power Ps and the current of the first electrode can be likened approximately to a straight line such that Ps=k×Ic1, k being a constant.

4. The method of measuring the RF power as claimed in claim 2, wherein the collector of the TWT comprises more than two stages and in that the relationship for the RF output power (Ps) of the TWT as a function of the collector current of the first electrode can be likened to a monotonically increasing polynominal.

5. The method of measuring the RF power as claimed in claim 2, wherein the relationship between the RF output power (Ps) and the current of the first electrode comprises a formula for interpolating the transmission frequency of the TWT.

6. The method of measuring the RF power as claimed in claim 2, wherein the collector of the TWT comprises more than two stages and in that the relationship for the RF output power (Ps) as a function of the collector current of the first electrode can be likened to a straight line, with more approximations than in the case of a two-stage TWT.

7. A microwave tube amplifier comprising:
an electron gun delivering an electron beam;
an RF circuit for interaction between an RF signal and the electron beam, the RF circuit having an amplified RF signal output, a collector having two electrodes for collecting the electron beam, these electrodes being respectively separated from the gun by increasing distances, the first electrode being closest to the gun;
first means for measuring the current coming from the first electrode and second means for determining the RF output power from the measurement of this current.

8. The microwave tube amplifier as claimed in claim 7, wherein the first means comprise an AC transformer for delivering the first electrode with current Ica at a measurement voltage proportional to said current.

9. The microwave tube amplifier as claimed in claim 8, wherein a high voltage supply for the amplifier comprising a TWT delivers, through a transformer, an AC alternating voltage U1 to a high-voltage rectifier bridge comprising rectifying diodes, that delivers the DC high voltage Vc1 and the current Ic1 of the first electrode of the TWT, the current transformer of the measurement circuit comprising a primary in series with a wire for supplying the high-voltage rectifier bridge with AC current and a secondary that generates an AC voltage Uc1 proportional to the AC current Ica in the wire representative of the supply current (Ic1) of the first electrode, the AC voltage Uc1, after rectification by a diode bridge, being amplified by a conventional operational amplifier delivering at its output a voltage Us1 proportional to the current Ic1 of the first electrode.

10. The microwave tube amplifier as claimed in claim 7, wherein the second means include a processing circuit of known type, which establishes the relationship between the output voltage Us1 of the detector representative of the current Ic1 and the output power Ps of the amplifier.

11. The microwave tube amplifier as claimed in claim 10, wherein the processing circuit may be a computer using a microprocessor or any other calculating device.

12. The method of claim 3, wherein relationship between the RF output power (Ps) and the current (Ic1) of the first electrode comprises a formula for interpolating the transmission frequency of the TWT.

13. The method of claim 4, wherein relationship between the RF output power (Ps) and the current (Ic1) of the first electrode comprises a formula for interpolating the transmission frequency of the TWT.

14. The method of claim 8, wherein the second means include a processing circuit of known type, which establishes the relationship between the output voltage of the detector representative of the current Ic1 and the output power Ps of the amplifier.

15. The method of claim 9, wherein the second means include a processing circuit of known type, which establishes the relationship between the output voltage of the detector representative of the current Ic1 and the output power Ps of the amplifier.
